(19) United States
(12) Patent Application Publication
(10) Pub. No.: US 2025/0023578 A1
(43) Pub. Date: Jan. 16, 2025

(54) WIDEBAND SIGNAL GENERATOR

(71) Applicant: Tektronix, Inc., Beaverton, OR (US)

(72) Inventor: Kan Tan, Portland, OR (US)

(21) Appl. No.: 18/739,160

(22) Filed: Jun. 10, 2024

Related U.S. Application Data
(60) Provisional application No. 63/513,102, filed on Jul. 11, 2023.

(51) Int. Cl. H03M 1/66; H04B 1/69

(52) U.S. Cl. CPC H03M 1/662; H04B 1/69

(57) ABSTRACT

A wideband signal generator has one or more digital-to-analog converters (DAC), each of the one or more DACs having one or more pipes and a sample rate, a multiplexer to receive analog outputs from at least two pipes from the one or more DACs and multiplex the analog outputs and zero into an output stream, a bandpass filter to receive the output stream and filter out frequency components in the output stream that are outside a target frequency band and produce a radio frequency (RF) output signal in the in the target frequency band, and one or more processors configured to execute code that causes the one or more processors to generate digital samples and transfer the digital samples to the one or more DACs, the digital samples generated to produce analog outputs that cause the RF output signal to match the target RF frequency band.

### CROSS-REFERENCE TO RELATED APPLICATIONS

This disclosure is a non-provisional of and claims benefit from U.S. Provisional Application No. 63/513,102, titled “WIDEBAND SIGNAL GENERATOR,” filed on Jul. 11, 2023, the disclosure of which is incorporated herein by reference in its entirety.

### TECHNICAL FIELD

This disclosure relates to test and measurement instruments, and more particularly to a wideband signal generator.

### BACKGROUND

High-speed signaling continues to progress to higher speed for wired and wireless communications. For example, 400 Gb (Gigabit) and 800 Gb Ethernet are being deployed and developed for data center and support wireless communication as the “backhaul.” The 5G wireless is being deployed and 6G wireless is under development. Both 5G and 6G are exploring high frequency bands. For example, 5G wireless explores the mmWave frequency band between 24 GHz and 300 GHz. Wireless 6G explores both mmWave and sub-THz (sub-Terahertz). The radio frequency (RF) range for signal generators needs to go up to 100 GHz and beyond.

As shown in FIG. 1, mobile unit 10 communicates with the base station 12 through the wireless channel 14 in the air space. Base station 12 connects to server 16 through the wired channel 18, for example, an optical cable. To achieve the 100 GHz and beyond transmission frequencies, current signal generators typically employ a mixer to upconvert the baseband signal from an arbitrary waveform generator (AWG) to the RF band, such as shown in FIG. 2. In FIG. 2, the signal generator comprises an AWG 20 to generate a baseband signal, and the mixer 22 upconverts it to an RF band. Filter 24 shapes the signal to ensure the signal in the target RF band is preserved, and out of band signals are removed. The signal generator needs to adjust the mixing signal to different frequencies for different target RF bands. Signal generators commonly use multi-stage mixing to generate target RF signals at higher frequency bands with wider instantaneous bandwidth (IBW).

### BRIEF DESCRIPTION OF THE DRAWINGS

FIG. 1 shows a diagram of a wired and wireless system for 5G/6G wireless.

FIG. 2 shows a diagram of a conventional radio frequency (RF) signal generator.

FIG. 3 shows an embodiment of a wideband signal generator (WSG) in accordance with the embodiments of the disclosure.

FIG. 4 shows an embodiment of pipe sampling time arrangements.

FIG. 5 shows an embodiment of bandpass filter bandwidth constraints.

FIG. 6 shows an embodiment of inputs and outputs for WSG algorithms.

FIG. 7 shows a diagram of a first frequency range case of an RF band.

FIG. 8 shows a diagram of a second frequency range case of an RF band.

FIG. 9 shows a diagram of a spectrum of samples from a first frequency range case.

FIG. 10 shows a diagram of a spectrum of samples from a second frequency range case.

FIG. 11 shows frames of a simulated WSG showing a high RF frequency range.

FIG. 12 shows frames of two tones of a simulated WSG with tones at one single tone in individual DAC pipe.

FIG. 13 shows frames showing a simulated WSG with one tone at DC.

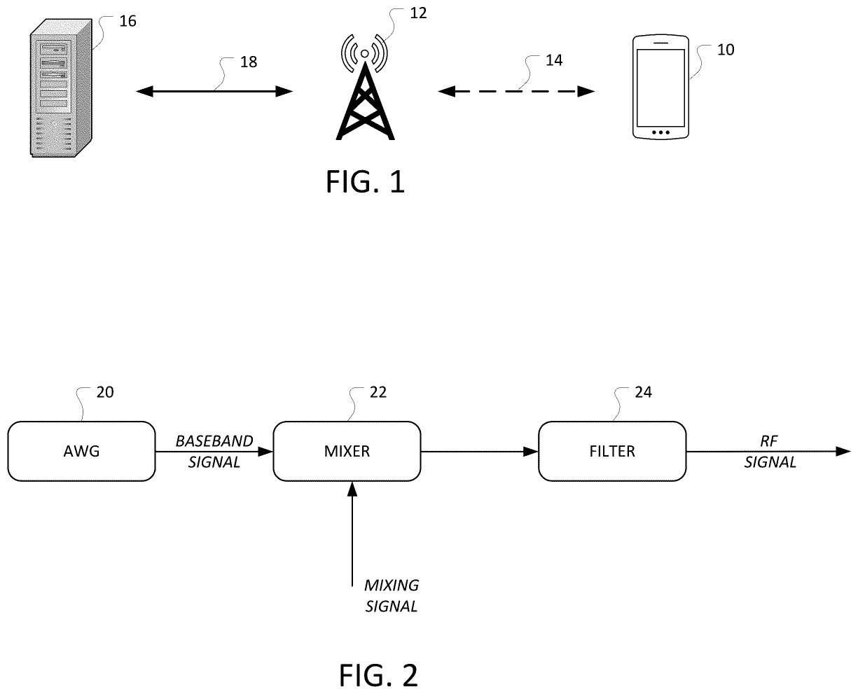

### DESCRIPTION

The embodiments herein describe a new instrument called Wideband Signal Generator (WSG) that uses a multiplexer and a bandpass filter with a paired digital-to-analog converters (DACs) to generate the wideband RF signal. The traditional mixer approach requires adjusting the frequency of the mixing signal to cover different RF bands. In comparison, the multiplexer in the WSG runs at a fixed rate. The WSG can be built with less complexity, lower the cost and the power consumption, having more RF channels in one single instrument.

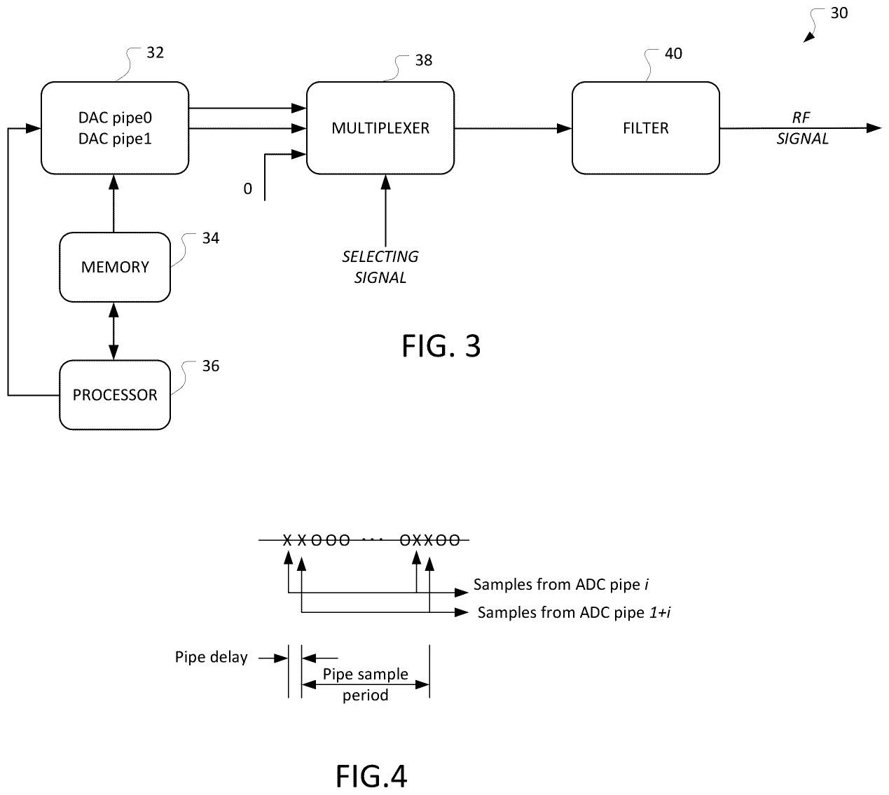

FIG. 3 shows a wideband signal generator (WSG) 30 in accordance with the embodiments of the disclosure. One or more processors such as 36 generate samples according to an algorithm. Memory 34 may load the samples created by the WSG algorithms into the DAC 32, or the processor 36 may load them into either the memory 34 or directly into the DAC 32. Processor 36 may comprise one or more processors, including a system processor, a specific field programmable gate array (FPGA), other DAC control processors, digital signal processors, among many others. As used herein, the terminology of “one or more processors configured to execute code” includes configuring an FPGA to generate the samples. The memory 34 and/or the processor 36 needs to have the capability to generate the digital samples according to the algorithms and send them to the DAC.

Multiplexer 38 switches between two different DAC pipes and zero in the pattern as shown in FIG. 3. The two DAC pipe may comprise two pipes from a single DAC, or it could be from two separate DACs. The pipes have a delay and a sample period, as shown in FIG. 4. The output of the multiplexer has the analog outputs in a sequence of:

. . . DAC0, DAC1, 0, 0, 0, . . . , 0, DAC0, DAC1, 0, 0, 0, . . . , 0, DAC0, DAC1, 0, 0, 0, . . .

A specific implementation of a WSG is designed based on the requirements on the RF range and the IBW. In the WSG, the DAC pipe delay and the pipe sample rate are chosen based on the following two conditions:
1. The inverse of the DAC pipe delay is more than twice of the target RF range of the WSG.
2. The DAC pipe sample rate is greater than the target IBW of the WSG.
   For example, to get the RF range of 110 GHz, and IBW of 12.5 GHZ, the pipe delay is chosen as 4 picoseconds (ps), the pipe sample rate is fₛ=15.625 GigaSamples/sec (GS/s). This configuration in WSG satisfies both conditions as 1/(4 ps)=250 GS/s>220 GHz (2×110 GHz), and 15.625 GHz>12.5 GHz. In this case, the DAC pipe sample period is 64 ps, or 16 times 4 ps.

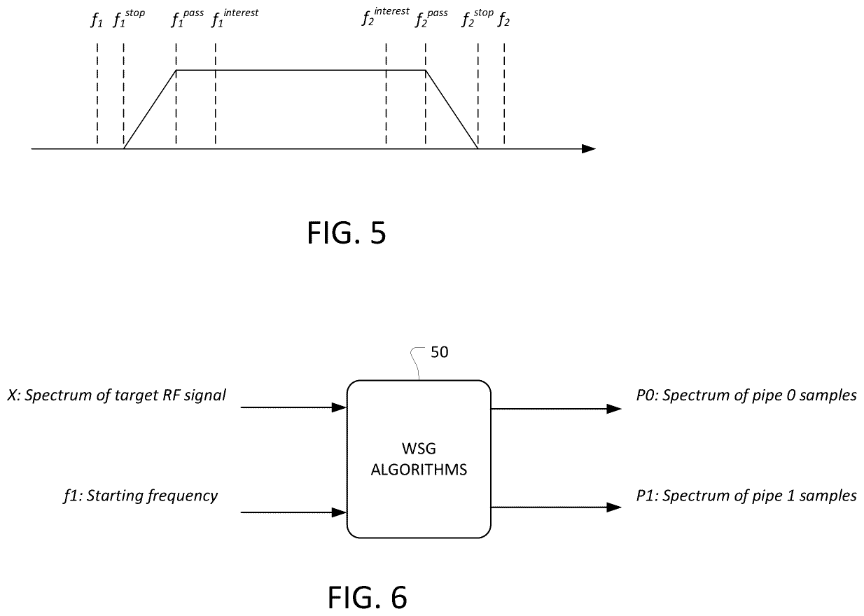

The filter in FIG. 3 comprises a bandpass (BP) filter in general, and it is chosen based on the following condition:
1. The BP filter bandwidth is greater than the target bandwidth of the WSG and narrower than the pipe sample rate. The BP filter pass band [f₁^{pass}, f₂^{pass}] covers the band of frequency of interest [f₁^{interest}, f₂^{interest}]. The frequency constraints are described in Equation (1) and shown in FIG. 5.

$${f}_{1} \leq {f}_{1}^{stop} < {f}_{1}^{pass} \leq {f}_{1}^{interest} < {f}_{2}^{interest} \leq {f}_{2}^{pass} < {f}_{2}^{stop} \leq {f}_{2} = {f}_{1} + {f}_{s} \qquad ( 1 )$$

In this example, the BP filter bandwidth is between the bandwidth of frequency of interest 12.5 GHz, and the pipe sample rate of 15.625 GHz. The BP filter can be fixed or tunable and can be composed of a filter bank, according to various embodiments of the disclosure. Low pass (LP) filters are treated as special BP filters. The BP filters can be built-in inside the instrument or be added as external attachments connected to the instrument outputs.

To generate the target RF signal, the WSG algorithms determine the samples for the two DAC pipes as shown in FIG. 6. The goal of the WSG algorithms is to compute the samples of the two DAC pipes, so that when the resulting analog outputs from the two pipes are multiplexed with 0, and then filtered by the filter in FIG. 3, the RF output matches the target RF signal. The one or more processors generate digital samples to send to the DAC pipes using the algorithms whether directly or through a memory, as discussed above. The digital samples are generated to cause the RF output to match the target RF signal.

In FIG. 6, f₁ is the starting frequency that satisfies the BP filter constraint defined in Equation (1). The WSG algorithms compute the spectra for the two DAC pipes. The digital samples for the DAC pipes can be obtained through IFFT on the spectra determined by the WSG algorithms.

FIG. 3 and Equation (1) show that the only frequency components in the frequency band between f₁ and f₁+fₛ pass through the BP filter stage as the final RF output. The BP filter filters out other frequency components in the output of the multiplexer. The WSG algorithms only needs to guarantee that the spectrum of the frequency components in the frequency band between f₁ and f₁+fₛ matches the spectrum of the target RF signal in the same frequency band.

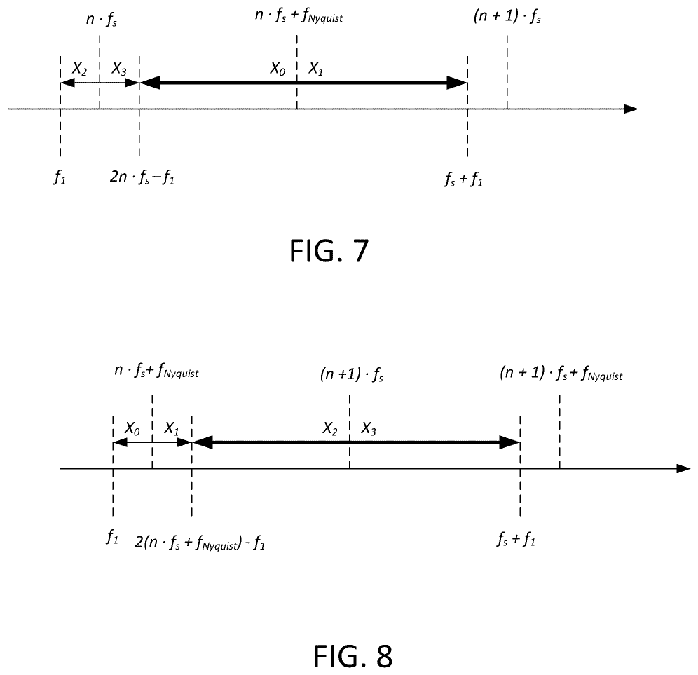

There are two cases to consider for the WSG algorithms. FIG. 7 shows Case 1, where the starting frequency f₁ is between an integer multiple of the sample rate fₛ and the integer multiple of fₛ minus the Nyquist frequency f_{Nyquist}=fₛ/2:

$$n \cdot {f}_{s} - {f}_{Nyquist} \leq {f}_{1} < n \cdot {f}_{s} n is an integer \qquad ( 2 )$$

FIG. 8 shows Case 2, where the starting frequency f₁ is between a multiple of sample rate fₛ and the multiple of fₛ plus the Nyquist frequency f_{Nyquist}.

$$n \cdot {f}_{s} \leq {f}_{1} < n \cdot {f}_{s} + {f}_{Nyquist} n is an integer \qquad ( 3 )$$

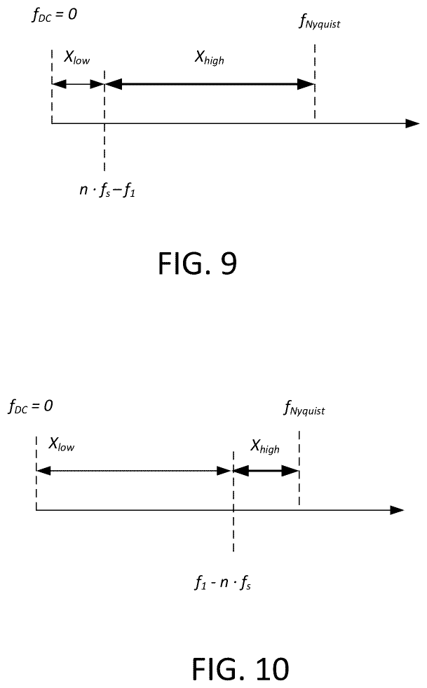

For Case 1 and Case 2, the DAC pipe0 and pipe1 digital samples determine the spectrum components of the output RF signal. The spectrum components of pipe0 and pipe1 determine the frequency components shown in FIGS. 7 and 8, which are between DC to f_{Nyquist}, as shown in FIGS. 9 and 10, respectively.

For Case 1, the spectrum X₂, X₃ around nfₛ in FIG. 7 are generated from the lower frequency X_{low} of the DAC pipe0 and pipe1 in FIG. 9. The spectrum X₀, X₁ around n·f+f_{Nyquist} in FIG. 7 are generated from the higher frequency X_{high} of the DAC pipe0 and pipe1 in FIG. 9.

With the following notations, one can see how the spectra can be determined for each pipe:
D: the delay from the DAC pipe0 to pipe1.
P₀: the spectrum of DAC pipe0 samples generated by the processor from the target spectrum.
p₀^{low}: the lower frequency part of P₀ between f_{DC} and n·fₛ−f₁. It is the pipe0 version of X_{low}.
p₀^{high}: the higher frequency part of P₀ between n·fₛ−f₁ and f_{Nyquist}. It is the pipe0 version of X_{high}.
f_{low}: the frequency of P₀^{low}, it is a vector.
f_{high}: the frequency of P₀^{high}, it is a vector.
P₁: the spectrum of DAC pipe1 samples generated by the processors from the target spectrum.
p₁^{low}: the lower frequency part of P₁ between f_{DC} and n·fₛ−f₁. It is the pipe1 version of X_{low}.
p₁^{high}: the higher frequency part of P₁ between n·fₛ−f₁ and f_{Nyquist}. It is the pipe1 version of X_{high}.

For Case 1, the solution for spectrum P₀^{low} and P₁^{low} in FIG. 10 can be derived as following:

$$K 1 = {e}^{j \cdot D \cdot 2 π \cdot ( n \cdot {f}_{s} - {f}_{low} )}$$

$$K 2 = {e}^{- j \cdot D \cdot 2 π \cdot ( n \cdot {f}_{s} + {f}_{low} )}$$

$${P}_{1}^{low} = \frac{{X}_{3} - flip ( complex conjugate ( {X}_{2} ) )}{K 2 - K 1} \qquad ( 4 )$$

$${P}_{0}^{low} = {X}_{3} - K 2 \cdot {P}_{1}^{low}$$

The P₀^{high} and P₁^{high} in FIG. 10 can be derived as following:

$$K 3 = {e}^{j \cdot D \cdot 2 π \cdot ( ( n + 1 ) \cdot {f}_{s} - {f}_{high} )} \qquad ( 5 )$$

$$K 4 = {e}^{- j \cdot D \cdot 2 π \cdot ( n \cdot {f}_{s} + {f}_{high} )}$$

$${P}_{1}^{high} = \frac{{X}_{0} - flip ( complex conjugate ( {X}_{1} ) )}{K 4 - K 3}$$

$${P}_{0}^{low} = {X}_{0} - K 4 \cdot {P}_{1}^{high}$$

The solution for Case 2 can be derived alike for Case 1.

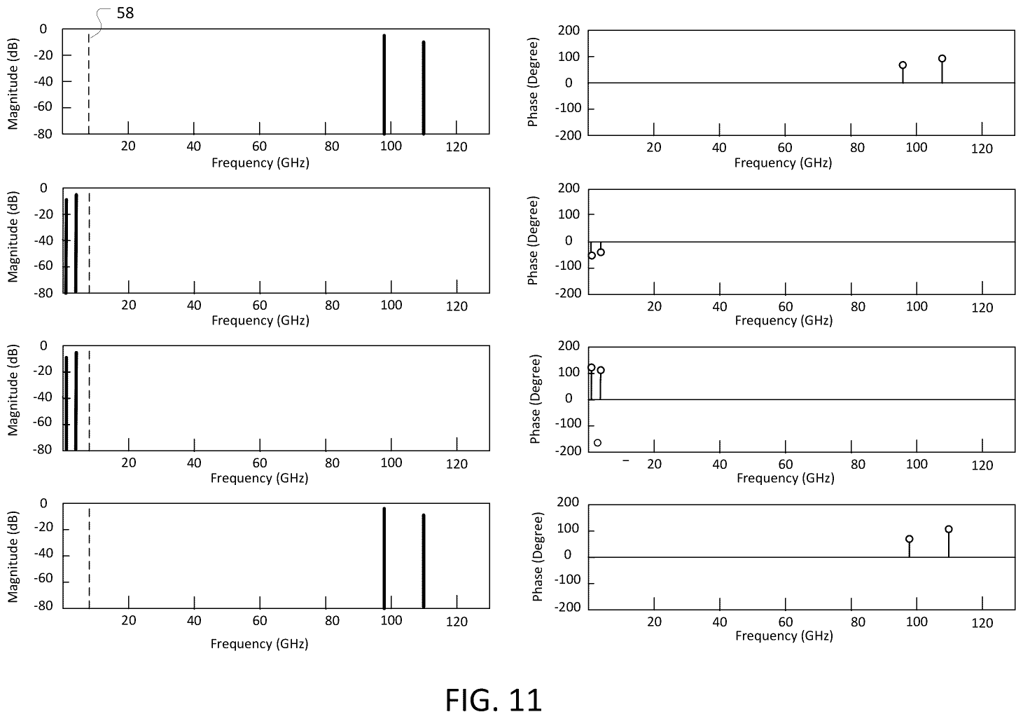

FIGS. 11-13 show a numerical example, each of which is one frame of an animated simulation of a two-tone signal sweeping to cover DC to 110 GHz, and the two tones are 12.5 GHz apart. At each frequency setting, the WSG algorithms determine the DAC pipe0 and pipe1 spectra. The pipe delay D=4 ps, each DAC pipe sample rate fₛ=15.625GS/s. As the two-tone signal sweeps, both Case 1 and Case 2 are covered. The numerical example demonstrates that RF range from DC to 110 GHz and IBW of 12.5 GHz are supported by the WSG.

Three frequency settings from the frequency sweep are shown in FIGS. 11-13.

The spectra of the two DAC pipes are bounded by f_{Nyquist} shown as the vertical dotted lines such as 58 in the left subplots. In the frame shown in FIG. 11, the magnitude spectra are different, and phases are different for two pipes. The WSG algorithms determine the digital samples to be generated and sent to the two DAC pipes. With the multiplexer 38 and the filter 40 in FIG. 3, the spectrum of the generated signal matches the spectrum of the target signal.

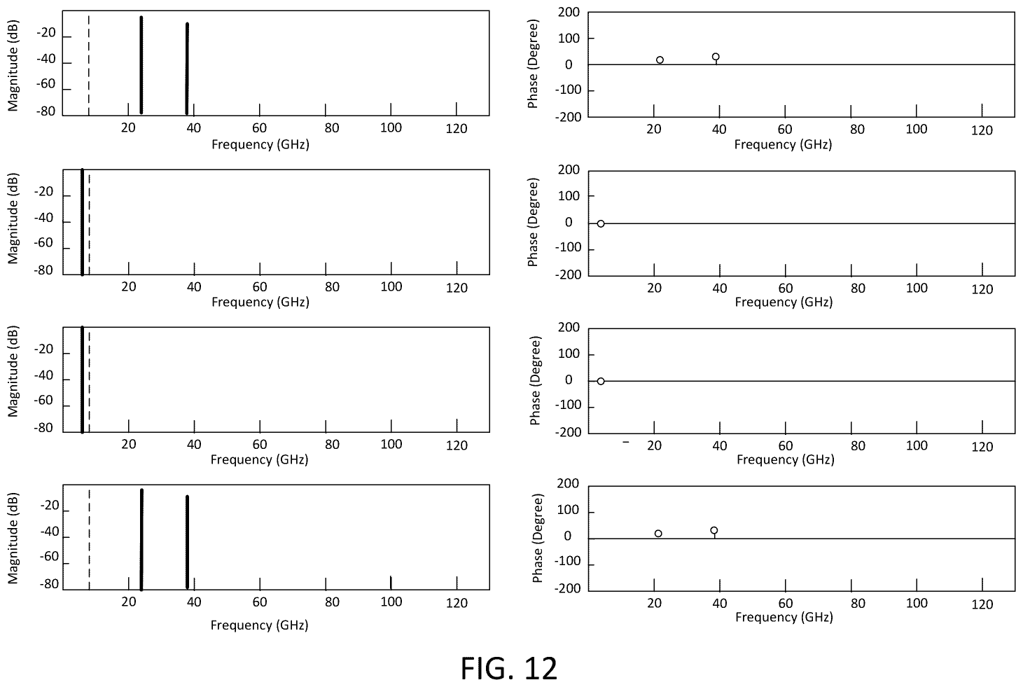

In the frequency setting shown in FIG. 12, both magnitude and phase spectra are different for the two DAC pipes. The spectrum of the generated signal matches the spectrum of the target RF signal.

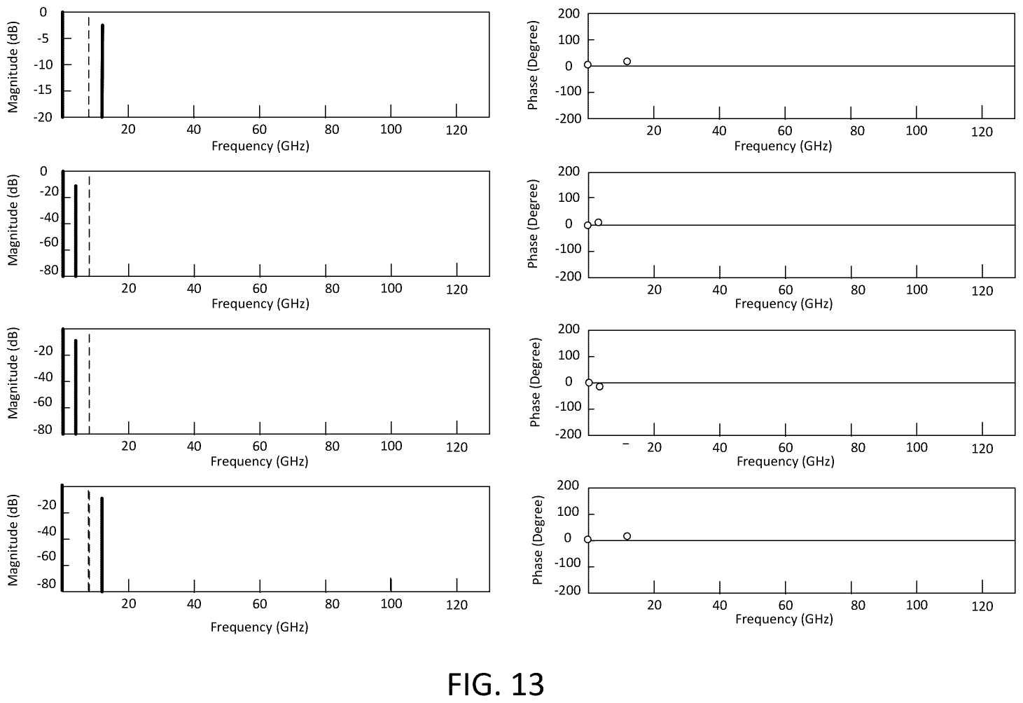

The frequency setting shown in FIG. 13 includes DC.

The traditional mixer-based RF signal generator system shown in FIG. 2 requires adjusting the frequency of the mixing signal to cover different RF bands. In comparison, the multiplexer in the WSG shown in FIG. 3 runs at a fixed rate and a fixed multiplexing sequence. The WSG can be built with less complexity, lower the cost and the power consumption, making it possible to support more RF channels in a single instrument. The WSG of the embodiments can adjust easily to different frequency bands desired by the user.

Having more RF channels in a single signal generator is desired for 5G wireless and 6G wireless testing. The Multiple-input-multiple-output (MIMO) is a key enabling technique for 5G wireless and 6G wireless systems. Multiple RF signals from a single signal generator can be better synchronized than the multiple RF signals from multiple separate signal generators. More RF channels also improve the testing throughput.

One consideration in selecting whether to use two DAC pipes from one DAC, or from different DACs, using two DAC pipes from one DAC may achieve better matching between the pipes, and more accurate calibration and higher SFDR (spurious free dynamic range).

The embodiments here describe a WSG that can be used for testing wideband high frequency RF applications such as 5G wireless and 6G wireless. The WSG has a simplified structure which uses the multiplexer in lieu of the mixer. The algorithms for the WSG determine the signals for the DACs based on the configuration of WSG and the target RF signal. The numerical example demonstrates the accurate RF signal generation by WSG. This WSG can operate at any target frequency band without having to make any mixing signal adjustments.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality May be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a wideband signal generator, comprising: one or more digital-to-analog converters (DAC), each of the one or more DACs having one or more pipes and a sample rate; a multiplexer to receive analog outputs from at least two pipes from the one or more DACs and multiplex the analog outputs and zero into an output stream; a bandpass filter to receive the output stream and filter out frequency components in the output stream that are outside a target frequency band and produce a radio frequency (RF) output signal in the in the target frequency band; and one or more processors configured to execute code that causes the one or more processors to generate digital samples and transfer the digital samples to the one or more DACs, the digital samples generated to produce analog outputs that cause the RF output signal to match the target RF frequency band.

Example 2 is the wideband signal generator of Example 1, wherein the one or more DACs comprise one DAC and the at least two pipes are from the one DAC.

Example 3 is the wideband signal generator as claimed in either of Example 1 or Example 2, wherein the one or more DACs comprise at least two DACs, and the at least two pipes comprise at least one pipe from each of the at least two DACs.

Example 4 is the wideband signal generator of any of Examples 1 through 3, wherein the one or more processors are configured to transfer the digital samples directly to the one or more DACs.

Example 5 is the wideband signal generator of any of Examples 1 through 4, further comprising a memory.

Example 6 is the wideband signal generator of Example 5, wherein the one or more processors are configured to transfer the digital samples to the memory, and the memory transfers the digital samples to the one or more DACs.

Example 7 is the wideband signal generator any of Examples 1 through 6, wherein the bandpass filter has a bandwidth greater than a target bandwidth of the RF output signal and narrower than the sample rate.

Example 8 is the wideband signal generator any of Examples 1 through 7, wherein the code that causes the one or more processors to generate digital samples causes the one or more processors to use a starting frequency and a spectrum of the target frequency band.

Example 9 is the wideband signal generator of Example 8, wherein the one or more processors are further configured to execute code that causes the one or more processors to set a pipe delay in the one or more DACs to be more than twice the target RF frequency band and the sample rate to be greater than an instantaneous bandwidth target of the wideband signal generator.

Example 10 is the wideband signal generator of Example 8, wherein the starting frequency is between a multiple of the sample rate and a multiple of the sample rate minus the Nyquist frequency.

Example 11 is the wideband signal generator of Example 8, wherein the starting frequency is between the sample rate and a multiple of the sample rate plus the Nyquist frequency.

Example 12 is a method of generating a wideband signal, comprising: using at least two pipes from one or more digital-to-analog converters (DAC), each of the one or more DACs having one or more pipes and a sample rate, to generate analog outputs; multiplexing the analog outputs from the at least two pipes and zero to produce an output stream; filtering the output stream to remove frequency components in the output stream outside a target frequency band and produce a radio frequency (RF) output signal in the in the target frequency band; and generating digital samples, the digital samples generated to cause the RF output signal matches the target RF frequency band.

Example 13 is the method of Example 12, wherein filtering the output stream comprises filtering the output stream with a bandpass filter having a bandwidth greater than a target bandwidth of the RF output signal and narrower than the sample rate.

Example 14 is the method of either of Examples 12 or 13, generating the digital samples comprises using a starting frequency and a spectrum of the target frequency band to determine a spectrum of the digital samples.

Example 15 the method of Example 14, further comprising setting a pipe delay in the one or more DACs to be more than twice the target RF frequency band and the sample rate to be greater than an instantaneous bandwidth target of the wideband signal generator.

Example 16 is the method of Example 14, wherein the starting frequency is between a multiple of the sample rate and a multiple of the sample rate minus the Nyquist frequency.

Example 17 is the method of Example 14, wherein the starting frequency is between the sample rate and a multiple of the sample rate plus the Nyquist frequency.

Example 18 is the method of any of Examples 12 through 17, wherein using the at least two pipes comprises using at least two pipes from one DAC.

Example 19 the method of any of Examples 12 through 17, wherein using the at least two pipes comprises using one pipe from each of at least two DACs.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A wideband signal generator, comprising:
one or more digital-to-analog converters (DAC), each of the one or more DACs having one or more pipes and a sample rate;
a multiplexer to receive analog outputs from at least two pipes from the one or more DACs and multiplex the analog outputs and zero into an output stream;
a bandpass filter to receive the output stream and filter out frequency components in the output stream that are outside a target frequency band and produce a radio frequency (RF) output signal in the in the target frequency band; and
one or more processors configured to execute code that causes the one or more processors to generate digital samples and transfer the digital samples to the one or more DACs, the digital samples generated to produce analog outputs that cause the RF output signal to match the target RF frequency band.

2. The wideband signal generator as claimed in claim 1, wherein the one or more DACs comprise one DAC and the at least two pipes are from the one DAC.

3. The wideband signal generator as claimed in claim 1, wherein the one or more DACs comprise at least two DACs, and the at least two pipes comprise at least one pipe from each of the at least two DACs.

4. The wideband signal generator as claimed in claim 1, wherein the one or more processors are configured to transfer the digital samples directly to the one or more DACs.

5. The wideband signal generator as claimed in claim 1, further comprising a memory.

6. The wideband signal generator as claimed in claim 5, wherein the one or more processors are configured to transfer the digital samples to the memory, and the memory transfers the digital samples to the one or more DACs.

7. The wideband signal generator as claimed in claim 1, wherein the bandpass filter has a bandwidth greater than a target bandwidth of the RF output signal and narrower than the sample rate.

8. The wideband signal generator as claimed in claim 1, wherein the code that causes the one or more processors to generate digital samples causes the one or more processors to use a starting frequency and a spectrum of the target frequency band.

9. The wideband signal generator as claimed in claim 8, wherein the one or more processors are further configured to execute code that causes the one or more processors to set a pipe delay in the one or more DACs to be more than twice the target RF frequency band and the sample rate to be greater than an instantaneous bandwidth target of the wideband signal generator.

10. The wideband signal generator as claimed in claim 8, wherein the starting frequency is between a multiple of the sample rate and a multiple of the sample rate minus the Nyquist frequency.

11. The wideband signal generator as claimed in claim 8, wherein the starting frequency is between the sample rate and a multiple of the sample rate plus the Nyquist frequency.

12. A method of generating a wideband signal, comprising:
using at least two pipes from one or more digital-to-analog converters (DAC), each of the one or more DACs having one or more pipes and a sample rate, to generate analog outputs;
multiplexing the analog outputs from the at least two pipes and zero to produce an output stream;
filtering the output stream to remove frequency components in the output stream outside a target frequency band and produce a radio frequency (RF) output signal in the in the target frequency band; and
generating digital samples, the digital samples generated to cause the RF output signal matches the target RF frequency band.

13. The method as claimed in claim 12, wherein filtering the output stream comprises filtering the output stream with a bandpass filter having a bandwidth greater than a target bandwidth of the RF output signal and narrower than the sample rate.

14. The method as claimed in claim 12, generating the digital samples comprises using a starting frequency and a spectrum of the target frequency band to determine a spectrum of the digital samples.

15. The method as claimed in claim 14, further comprising setting a pipe delay in the one or more DACs to be more than twice the target RF frequency band and the sample rate to be greater than an instantaneous bandwidth target of the wideband signal generator.

16. The method as claimed in claim 14, wherein the starting frequency is between a multiple of the sample rate and a multiple of the sample rate minus the Nyquist frequency.

17. The method as claimed in claim 14, wherein the starting frequency is between the sample rate and a multiple of the sample rate plus the Nyquist frequency.

18. The method as claimed in claim 12, wherein using the at least two pipes comprises using at least two pipes from one DAC.

19. The method as claimed in claim 12, wherein using the at least two pipes comprises using one pipe from each of at least two DACs.
